(19) United States
(12) Patent Application Publication
(10) Pub. No.: US 2025/0291373 A1
(43) Pub. Date: Sep. 18, 2025

(54) WIDE-BANDWIDTH POWER MANAGEMENT INTEGRATED CIRCUIT

(71) Applicant: Qorvo US, Inc., Greensboro, NC (US)

(72) Inventor: Nadim Khlat, Cugnaux (FR)

(21) Appl. No.: 19/044,718

(22) Filed: Feb. 4, 2025

Related U.S. Application Data
(60) Provisional application No. 63/566,534, filed on Mar. 18, 2024.
(60) Provisional application No. 63/647,290, filed on May 14, 2024.

(51) Int. Cl. G05F 1/46; H03F 3/24

(52) U.S. Cl. CPC G05F 1/46; H03F 3/245

(57) ABSTRACT

A wide-bandwidth power management integrated circuit (PMIC) is disclosed. Herein, the wide-bandwidth PMIC is configured to modulate a voltage, such as an envelope tracking (ET) or an average power tracking (APT) voltage, across a wide modulation bandwidth (e.g., 400 MHZ). In embodiments disclosed herein, the wide-bandwidth PMIC includes a regular-bandwidth voltage circuit and a high-bandwidth voltage circuit. The regular-bandwidth voltage circuit is configured to modulate the voltage up to a defined bandwidth threshold (e.g., 100 MHz), whereas the high-bandwidth voltage circuit is configured to modulate the voltage beyond the defined bandwidth threshold. In this regard, each of the regular-bandwidth voltage circuit and the high-bandwidth voltage circuit can be optimized based on a respective modulation bandwidth for the best-possible efficiency and performance.

### RELATED APPLICATIONS

This application claims the benefit of U.S. provisional patent application Ser. No. 63/566,534, filed on Mar. 18, 2024, and U.S. provisional patent application Ser. No. 63/647,290, filed on May 14, 2024, the disclosures of which are hereby incorporated herein by reference in their entireties.

### FIELD OF THE DISCLOSURE

The present disclosure is related to a power management integrated circuit (PMIC) operable over a wide modulation bandwidth (e.g., ≥400 MHZ).

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by such advanced wireless communication technologies as fifth-generation new-radio (5G-NR). To achieve higher data rates, a mobile communication device is required to amplify a transmission signal to a desired power level to help overcome potential propagation losses and/or interferences. As such, the mobile communication device typically includes a transceiver circuit(s), a power amplifier circuit(s), and a power management circuit(s). Specifically, the transceiver circuit(s) modulates the transmission signal to an intended transmission frequency, the power amplifier circuit(s) amplifies the transmission signal to the desired power level, and the power management circuit(s) supplies an envelope tracking (ET) or an average power tracking (APT) modulated voltage to the power amplifier circuit(s). Understandably, to achieve the best possible efficiency and performance, the power management circuit(s) must adapt the ET/APT voltage in accordance with a modulation bandwidth of the transmission signal.

### SUMMARY

Embodiments of the disclosure relate to a wide-bandwidth power management integrated circuit (PMIC). Herein, the wide-bandwidth PMIC is configured to modulate a voltage, such as an envelope tracking (ET) or an average power tracking (APT) voltage, across a wide modulation bandwidth (e.g., 400 MHZ). In embodiments disclosed herein, the wide-bandwidth PMIC includes a regular-bandwidth voltage circuit and a high-bandwidth voltage circuit. The regular-bandwidth voltage circuit is configured to modulate the voltage up to a defined bandwidth threshold (e.g., 100 MHz), whereas the high-bandwidth voltage circuit is configured to modulate the voltage beyond the defined bandwidth threshold. In this regard, each of the regular-bandwidth voltage circuit and the high-bandwidth voltage circuit can be optimized based on a respective modulation bandwidth for the best-possible efficiency and performance.

In one aspect, a wide-bandwidth PMIC is provided. The wide-bandwidth PMIC includes a regular-bandwidth voltage circuit. The regular-bandwidth voltage circuit is configured to generate a modulated voltage having a lower modulation bandwidth at a voltage output. The wide-bandwidth PMIC also includes a high-bandwidth voltage circuit. The high-bandwidth voltage circuit is configured to generate the modulated voltage having a higher modulation bandwidth at the voltage output. The wide-bandwidth PMIC also includes a control circuit. The control circuit is configured to activate the regular-bandwidth voltage circuit and deactivate the high-bandwidth voltage circuit when a modulation bandwidth of the modulated voltage is lower than or equal to a defined bandwidth threshold. The control circuit is also configured to activate the high-bandwidth voltage circuit and deactivate the regular-bandwidth voltage circuit when the modulation bandwidth of the modulated voltage is higher than the defined bandwidth threshold.

In another aspect, a wireless device is provided. The wireless device includes a power amplifier circuit. The power amplifier circuit is configured to amplify a transmission signal based on a modulated voltage. The wireless device also includes a wide-bandwidth PMIC. The wide-bandwidth PMIC includes a regular-bandwidth voltage circuit. The regular-bandwidth voltage circuit is configured to generate the modulated voltage having a lower modulation bandwidth at a voltage output. The wide-bandwidth PMIC also includes a high-bandwidth voltage circuit. The high-bandwidth voltage circuit is configured to generate the modulated voltage having a higher modulation bandwidth at the voltage output. The wide-bandwidth PMIC also includes a control circuit. The control circuit is configured to activate the regular-bandwidth voltage circuit and deactivate the high-bandwidth voltage circuit when a modulation bandwidth of the modulated voltage is lower than or equal to a defined bandwidth threshold. The control circuit is also configured to activate the high-bandwidth voltage circuit and deactivate the regular-bandwidth voltage circuit when the modulation bandwidth of the modulated voltage is higher than the defined bandwidth threshold.

In another aspect, a method for operating a wide-bandwidth PMIC is provided. The method includes configuring a regular-bandwidth voltage circuit to generate a modulated voltage having a lower modulation bandwidth at a voltage output. The method also includes configuring a high-bandwidth voltage circuit to generate the modulated voltage having a higher modulation bandwidth at the voltage output. The method also includes activating the regular-bandwidth voltage circuit and deactivating the high-bandwidth voltage circuit when a modulation bandwidth of the modulated voltage is lower than or equal to a defined bandwidth threshold. The method also includes activating the high-bandwidth voltage circuit and deactivating the regular-bandwidth voltage circuit when the modulation bandwidth of the modulated voltage is higher than the defined bandwidth threshold.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary wide-bandwidth power management integrated circuit (PMIC) configured according to embodiments of the present disclosure to generate a modulated voltage across a wide modulation bandwidth;

FIGS. 2A and 2B are schematic diagrams illustrating exemplary operating scenarios of the wide-bandwidth PMIC of FIG. 1;

FIG. 3 is a schematic diagram of an exemplary communication device wherein the wide-bandwidth PMIC of FIG. 1 can be provided; and

FIG. 4 is a flowchart of an exemplary process for operating the wide-bandwidth PMIC of FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to a wide-bandwidth power management integrated circuit (PMIC). Herein, the wide-bandwidth PMIC is configured to modulate a voltage, such as an envelope tracking (ET) or an average power tracking (APT) voltage, across a wide modulation bandwidth (e.g., 400 MHZ). In embodiments disclosed herein, the wide-bandwidth PMIC includes a regular-bandwidth voltage circuit and a high-bandwidth voltage circuit. The regular-bandwidth voltage circuit is configured to modulate the voltage up to a defined bandwidth threshold (e.g., 100 MHZ), whereas the high-bandwidth voltage circuit is configured to modulate the voltage beyond the defined bandwidth threshold. In this regard, each of the regular-bandwidth voltage circuit and the high-bandwidth voltage circuit can be optimized based on a respective modulation bandwidth for the best-possible efficiency and performance.

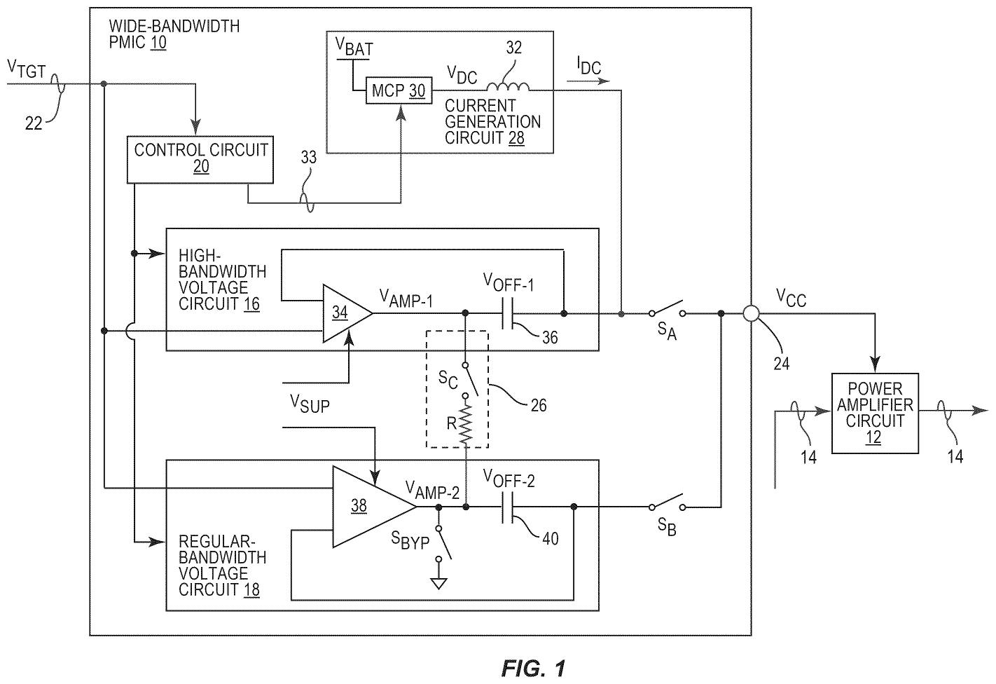

FIG. 1 is a schematic diagram of an exemplary wide-bandwidth PMIC 10 configured according to embodiments of the present disclosure to generate a modulated voltage V_{cc} across a wide modulation bandwidth. Herein, the wide-bandwidth PMIC 10 is configured to provide the modulated voltage V_{cc} to a power amplifier circuit 12 for amplifying a transmission signal 14. The transmission signal 14 is modulated by a transceiver circuit (not shown) onto a radio frequency (RF) transmission band(s). Given that the RF transmission band(s) can be allocated across a wide RF frequency range, the wide-bandwidth PMIC 10 must be configured to provide the modulated voltage V_{cc} across the wide modulation bandwidth to help achieve the best-possible efficiency and performance at the power amplifier circuit 12.

Thus, in an embodiment, the wide-bandwidth PMIC 10 is configured to include a high-bandwidth voltage circuit 16 and a regular-bandwidth voltage circuit 18, each configured to generate the modulated voltage V_{cc} based on a modulated target voltage V_{IGT} and a supply voltage Vₛᵤₚ. As the name suggests, the high-bandwidth voltage circuit 16 is designed and optimized to handle a higher modulation bandwidth (e.g., ≥100 MHZ), whereas the regular-bandwidth voltage circuit 18 is designed and optimize to handle a lower modulation bandwidth (e.g., ≤100 MHZ). In this regard, at any given time, only one of the high-bandwidth voltage circuit 16 and the regular-bandwidth voltage circuit 18 will be activated to supply the modulated voltage V_{cc} to the power amplifier circuit 12.

In an embodiment, the wide-bandwidth PMIC 10 includes a control circuit 20. The control circuit 20 is configured to receive an indication signal 22 that indicates the intended modulation bandwidth. In a non-limiting example, the control circuit 20 can receive the indication signal 22 from the transceiver circuit over an RF frontend (RFFE) interface.

In this regard, the control circuit 20 can compare the modulation bandwidth received via the indication signal 22 against a defined bandwidth threshold (e.g., 100 MHZ), which may be indicated by the indication signal 22 or preprogrammed into the control circuit 20, to determine which of the high-bandwidth voltage circuit 16 and the regular-bandwidth voltage circuit 18 is to be activated. When the modulation bandwidth is lower than or equal to the defined bandwidth threshold, the control circuit 20 activates the regular-bandwidth voltage circuit 18 and deactivates the high-bandwidth voltage circuit 16. In contrast, when the modulation bandwidth is higher than the defined bandwidth threshold, the control circuit 20 activates the high-bandwidth voltage circuit 16 and deactivates the regular-bandwidth voltage circuit 18.

In an embodiment, the wide-bandwidth PMIC 10 includes a first switch S_{A} and a second switch S_{B}. The first switch S_{A} is coupled between the high-bandwidth voltage circuit 16 and a voltage output 24. The second switch S_{B} is coupled between the regular-bandwidth voltage circuit 18 and the voltage output 24. The wide-bandwidth PMIC 10 also includes a high impedance path 26, which includes a third switch Sc and a resistor R that are coupled in series between the high-bandwidth voltage circuit 16 and the regular-bandwidth voltage circuit 18.

The wide-bandwidth PMIC 10 also includes a current generation circuit 28. The current generation circuit 28 is coupled to the voltage output 24 via the first switch S_{A}. Specifically, the current generation circuit 28 includes a multi-level charge pump (MCP) 30 and a power inductor 32. The power inductor 32 is coupled between the MCP 30 and the first switch S_{A}. Herein, the MCP 30 is configured by a duty cycle signal 33 to generate a low-frequency voltage V_{Dc} as a function of a battery voltage V_{BAT} and the power inductor 32 is configured to induce a low-frequency current loc based on the low-frequency voltage V_{Dc}. In an embodiment, the control circuit 20 can be configured to generate the duty cycle signal 33 in accordance with a modulated target voltage VTGT that indicates a target level of the modulated voltage V_{cc}.

In an embodiment, the MCP 30 is a buck-boost voltage converter that can toggle between a buck mode and a boost mode in accordance with the duty cycle signal 33. Specifically, in the buck mode, the MCP 30 can generate the low-frequency voltage V_{Dc} at 0 V (0×V_{BAT}) or the battery voltage V_{BAT} (1×V_{BAT}), whereas in the boost mode, the MCP 30 can generate the low-frequency voltage V_{DC} at twice the battery voltage V_{BAT} (2×V_{BAT}). Thus, by modulating the low-frequency voltage V_{Dc} in accordance with the duty cycle signal 33, the low-frequency current I_{DC} can be modulated accordingly.

The high-bandwidth voltage circuit 16 includes a first voltage amplifier 34 and a first offset capacitor 36. The first voltage amplifier 34 is configured to generate a first modulated voltage V_{AMP-1} associated with the higher modulation bandwidth (e.g., >100 MHZ). The first offset capacitor 36 is coupled between the first voltage amplifier 34 and the first switch S_{A}. Herein, the first offset capacitor 36 is configured to raise the first modulated voltage V_{AMP-1} by a first offset voltage V_{OFF-1} to thereby generate the modulated voltage V_{cc} (V_{cc}=V_{AMP-1}+V_{OFF-1}) at the higher modulation bandwidth.

The regular-bandwidth voltage circuit 18 includes a second voltage amplifier 38 and a second offset capacitor 40. The second voltage amplifier 38 is configured to generate a second modulated voltage V_{AMP-2} associated with the lower modulation bandwidth (e.g., ≤100 MHZ). The second offset capacitor 40 is coupled between the second voltage amplifier 38 and the second switch S_{B}. Herein, the second offset capacitor 40 is configured to raise the second modulated voltage V_{AMP-2} by a second offset voltage V_{OFF-2} to thereby generate the modulated voltage V_{cc} (V_{cc}=V_{AMP-2}+V_{OFF-2}) at the lower modulation bandwidth. The regular-bandwidth voltage circuit 18 may further include a bypass switch S_{BYP}, which can be closed to expedite the transition (e.g., decrease) of the modulated voltage V_{cc}.

According to an embodiment of the present disclosure, the first modulated voltage V_{AMP-1} is designed to have a lower peak than the second modulated voltage V_{AMP-2}. As such, the first voltage amplifier 34 can have a smaller output stage (e.g., smaller transistors) than that in the second voltage amplifier 38.

Herein, the high-bandwidth voltage circuit 16 is said to be activated when the first voltage amplifier 34 is enabled, and deactivated when the first voltage amplifier 34 is disabled. Likewise, the regular-bandwidth voltage circuit 18 is said to be activated when the second voltage amplifier 38 is enabled, and deactivated when the second voltage amplifier 38 is disabled. In this regard, the control circuit 20 can be configured to enable the second voltage amplifier 38 and disable the first voltage amplifier 34 when the modulation bandwidth of the modulated voltage V_{cc} is lower than or equal to the defined bandwidth threshold. The control circuit 20 can be further configured to enable the first voltage amplifier 34 and disable the second voltage amplifier 38 when the modulation bandwidth of the modulated voltage V_{cc} is higher than the defined bandwidth threshold.

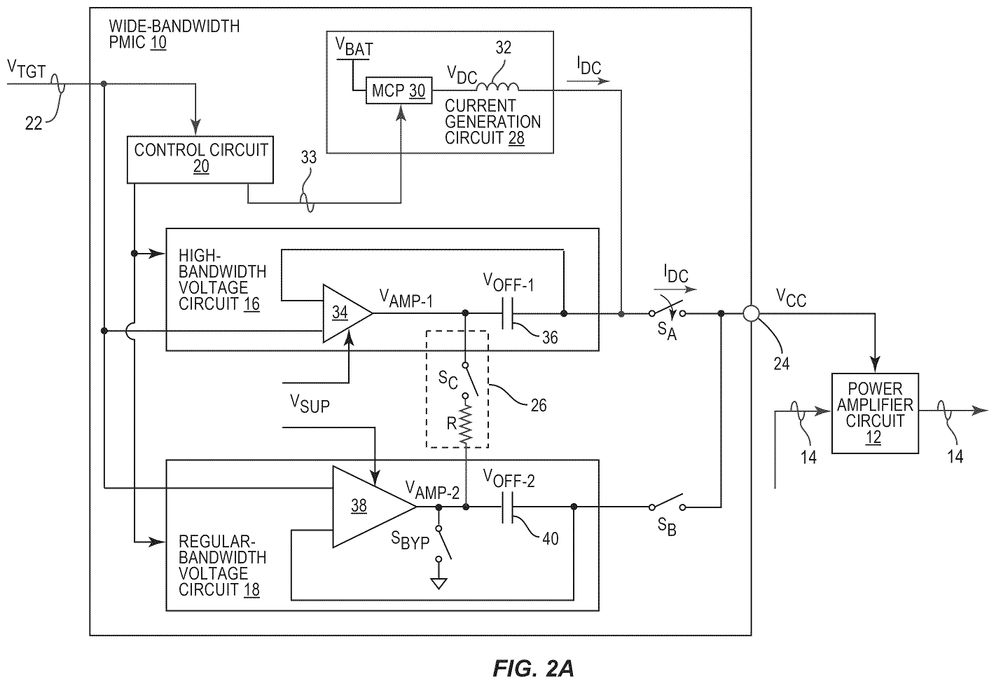

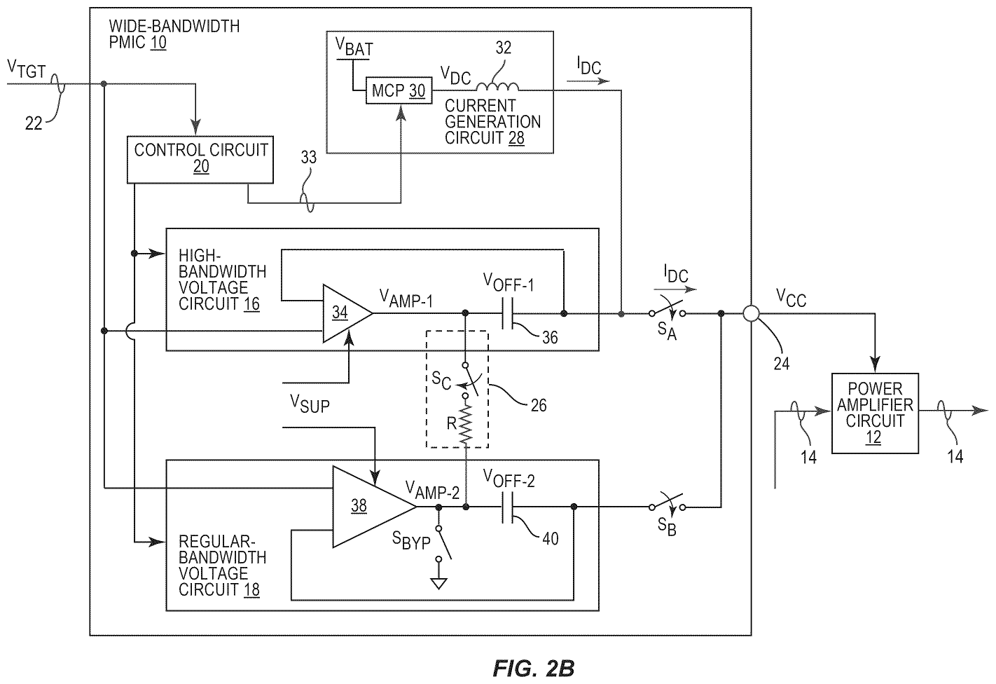

FIGS. 2A and 2B are schematic diagrams illustrating exemplary operating scenarios of the wide-bandwidth PMIC 10 of FIG. 1. Common elements between FIGS. 1 and 2A-2B are shown therein with common element numbers and will not be re-described herein.

FIG. 2A illustrates the operating scenario where the modulation bandwidth is above the defined bandwidth threshold. Herein, the control circuit 20 enables the first voltage amplifier 34 and disables the second voltage amplifier 38. The control circuit 20 also closes the first switch S_{A}, while keeping the second switch S_{B} and the third switch Sc open, such that the low-frequency current I_{DC} can flow to the power amplifier circuit 12 via the voltage output 24.

FIG. 2B illustrates the operating scenario where the modulation bandwidth is lower than or equal to the defined bandwidth threshold. Herein, the control circuit 20 disables the first voltage amplifier 34 and enables the second voltage amplifier 38. The control circuit 20 also concurrently closes the first switch S_{A}, the second switch S_{B}, and the third switch Sc. Specifically, by closing the third switch Sc, the high impedance path 26 can thus present a higher impedance to prevent the first voltage amplifier 34 from floating.

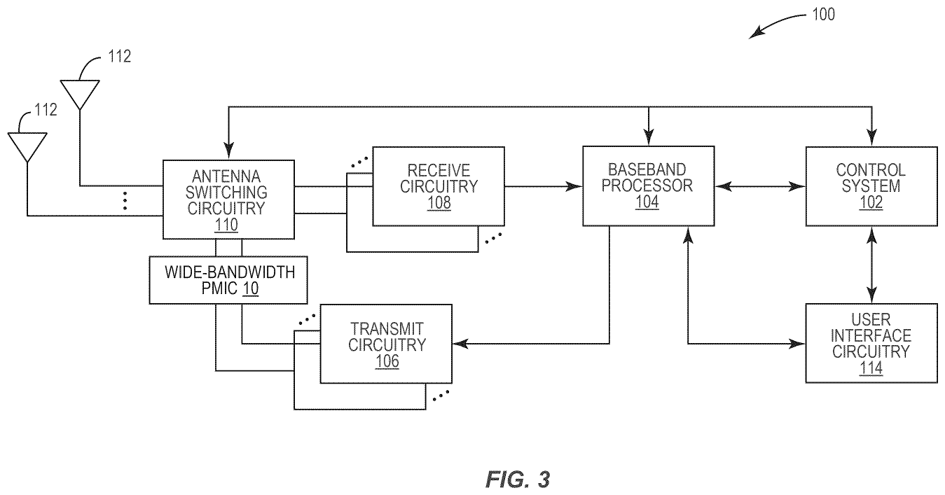

The wide-bandwidth PMIC 10 of FIG. 1 can be provided in a communication device to support the embodiments described above. In this regard, FIG. 3 is a schematic diagram of an exemplary communication device 100 wherein the wide-bandwidth PMIC 10 of FIG. 1 can be provided.

Herein, the communication device 100 can be any type of communication device, such as a mobile terminal, smart watch, tablet, computer, navigation device, access point, base station (e.g., eNB, gNB, etc.), and like wireless communication devices that support wireless communications, such as cellular, wireless local area network (WLAN), Ultra-wideband (UWB), Bluetooth, and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In an embodiment, the transmit circuitry 106 and the receive circuitry 108 can function as a transceiver circuit. Accordingly, the wide-bandwidth PMIC 10 can be provided between the transmit circuitry 106 and the antenna switching circuitry 110.

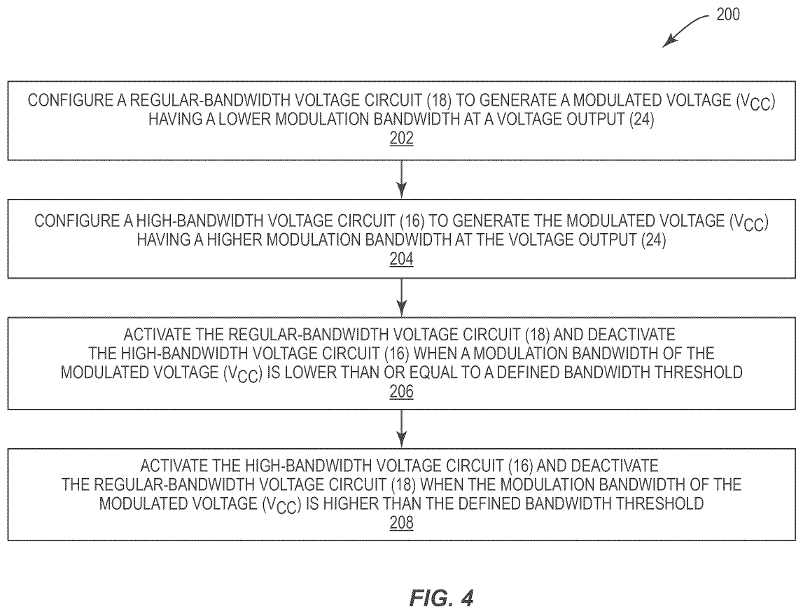

In an embodiment, the wide-bandwidth PMIC 10 of FIG. 1 can be operated in accordance with a process. In this regard, FIG. 4 is a flowchart of an exemplary process 200 for operating the wide-bandwidth PMIC 10 of FIG. 1.

Herein, the process 200 includes configuring the regular-bandwidth voltage circuit 18 to generate the modulated voltage V_{cc} having the lower modulation bandwidth at the voltage output 24 (step 202). The process 200 also includes configuring the high-bandwidth voltage circuit 16 to generate the modulated voltage V_{cc} having the higher modulation bandwidth at the voltage output 24 (step 204). The process 200 also includes activating the regular-bandwidth voltage circuit 18 and deactivating the high-bandwidth voltage circuit 16 when the modulation bandwidth of the modulated voltage V_{cc} is lower than or equal to the defined bandwidth threshold (step 206). The process 200 also includes activating the high-bandwidth voltage circuit 16 and deactivating the regular-bandwidth voltage circuit 18 when the modulation bandwidth of the modulated voltage V_{cc} is higher than the defined bandwidth threshold (step 208).

Those skilled in the art will recognize improvements and modifications to the preferred embodiments of the present disclosure. All such improvements and modifications are considered within the scope of the concepts disclosed herein and the claims that follow.

What is claimed is:

1. A wide-bandwidth power management integrated circuit (PMIC) comprising:
a regular-bandwidth voltage circuit configured to generate a modulated voltage having a lower modulation bandwidth at a voltage output;
a high-bandwidth voltage circuit configured to generate the modulated voltage having a higher modulation bandwidth at the voltage output; and
a control circuit configured to:
activate the regular-bandwidth voltage circuit and deactivate the high-bandwidth voltage circuit when a modulation bandwidth of the modulated voltage is lower than or equal to a defined bandwidth threshold; and
activate the high-bandwidth voltage circuit and deactivate the regular-bandwidth voltage circuit when the modulation bandwidth of the modulated voltage is higher than the defined bandwidth threshold.

2. The wide-bandwidth PMIC of claim 1, wherein the control circuit is further configured to determine the modulation bandwidth of the modulated voltage based on an indication signal received via a radio frequency frontend (RFFE) interface.

3. The wide-bandwidth PMIC of claim 1, further comprising:
a first switch coupled between the high-bandwidth voltage circuit and the voltage output;
a second switch coupled between the regular-bandwidth voltage circuit and the voltage output;
a high impedance path comprising a third switch and a resistor coupled in series between the regular-bandwidth voltage circuit and the high-bandwidth voltage circuit; and
a current generation circuit coupled to the voltage output via the first switch and configured to generate a low-frequency current in accordance with a duty cycle signal.

4. The wide-bandwidth PMIC of claim 3, wherein the current generation circuit comprises:
a multi-level charge pump (MCP) configured to modulate a low-frequency voltage as a function of a battery voltage in accordance with the duty cycle signal; and
a power inductor coupled between the MCP and the first switch and configured to induce the low-frequency current based on the low-frequency voltage.

5. The wide-bandwidth PMIC of claim 3, wherein:
the high-bandwidth voltage circuit comprises:
a first voltage amplifier configured to generate a first modulated voltage having the higher modulation bandwidth; and
a first offset capacitor coupled between the first voltage amplifier and the first switch and configured to raise the first modulated voltage by a first offset voltage to thereby generate the modulated voltage at the higher modulation bandwidth; and
the regular-bandwidth voltage circuit comprises:
a second voltage amplifier configured to generate a second modulated voltage having the lower modulation bandwidth; and
a second offset capacitor coupled between the second voltage amplifier and the second switch and configured to raise the second modulated voltage by a second offset voltage to thereby generate the modulated voltage at the lower modulation bandwidth.

6. The wide-bandwidth PMIC of claim 5, wherein the first voltage amplifier is configured to have a smaller output stage than the second voltage amplifier.

7. The wide-bandwidth PMIC of claim 5, wherein the control circuit is further configured to:
enable the second voltage amplifier and disable the first voltage amplifier when the modulation bandwidth of the modulated voltage is lower than or equal to the defined bandwidth threshold; and
enable the first voltage amplifier and disable the second voltage amplifier when the modulation bandwidth of the modulated voltage is higher than the defined bandwidth threshold.

8. The wide-bandwidth PMIC of claim 3, wherein, when the modulation bandwidth of the modulated voltage is higher than the defined bandwidth threshold, the control circuit is further configured to close the first switch while keeping the second switch and the third switch open.

9. The wide-bandwidth PMIC of claim 3, wherein, when the modulation bandwidth of the modulated voltage is lower than or equal to the defined bandwidth threshold, the control circuit is further configured to close the first switch, the second switch, and the third switch.

10. A wireless device comprising:
a power amplifier circuit configured to amplify a transmission signal based on a modulated voltage; and
a wide-bandwidth power management integrated circuit (PMIC) comprising:
a regular-bandwidth voltage circuit configured to generate the modulated voltage having a lower modulation bandwidth at a voltage output;
a high-bandwidth voltage circuit configured to generate the modulated voltage having a higher modulation bandwidth at the voltage output; and
a control circuit configured to:
activate the regular-bandwidth voltage circuit and deactivate the high-bandwidth voltage circuit when a modulation bandwidth of the modulated voltage is lower than or equal to a defined bandwidth threshold; and
activate the high-bandwidth voltage circuit and deactivate the regular-bandwidth voltage circuit when the modulation bandwidth of the modulated voltage is higher than the defined bandwidth threshold.

11. The wireless device of claim 10, wherein the control circuit is further configured to determine the modulation bandwidth of the modulated voltage based on an indication signal received via a radio frequency frontend (RFFE) interface.

12. The wireless device of claim 11, further comprising a transceiver circuit configured to generate the transmission signal and provide the indication signal to the control circuit via the RFFE interface.

13. The wireless device of claim 10, wherein the wide-bandwidth PMIC further comprises:
a first switch coupled between the high-bandwidth voltage circuit and the voltage output;
a second switch coupled between the regular-bandwidth voltage circuit and the voltage output;
a high impedance path comprising a third switch and a resistor coupled in series between the regular-bandwidth voltage circuit and the high-bandwidth voltage circuit; and
a current generation circuit coupled to the voltage output via the first switch and configured to generate a low-frequency current in accordance with a duty cycle signal.

14. The wireless device of claim 13, wherein the current generation circuit comprises:
a multi-level charge pump (MCP) configured to modulate a low-frequency voltage as a function of a battery voltage in accordance with the duty cycle signal; and
a power inductor coupled between the MCP and the first switch and configured to induce the low-frequency current based on the low-frequency voltage.

15. The wireless device of claim 13, wherein:
the high-bandwidth voltage circuit comprises:
a first voltage amplifier configured to generate a first modulated voltage having the higher modulation bandwidth; and
a first offset capacitor coupled between the first voltage amplifier and the first switch and configured to raise the first modulated voltage by a first offset voltage to thereby generate the modulated voltage at the higher modulation bandwidth; and
the regular-bandwidth voltage circuit comprises:
a second voltage amplifier configured to generate a second modulated voltage having the lower modulation bandwidth; and
a second offset capacitor coupled between the second voltage amplifier and the second switch and configured to raise the second modulated voltage by a second offset voltage to thereby generate the modulated voltage at the lower modulation bandwidth.

16. The wireless device of claim 15, wherein the first voltage amplifier is configured to have a smaller output stage than the second voltage amplifier.

17. The wireless device of claim 15, wherein the control circuit is further configured to:
enable the second voltage amplifier and disable the first voltage amplifier when the modulation bandwidth of the modulated voltage is lower than or equal to the defined bandwidth threshold; and
enable the first voltage amplifier and disable the second voltage amplifier when the modulation bandwidth of the modulated voltage is higher than the defined bandwidth threshold.

18. The wireless device of claim 13, wherein, when the modulation bandwidth of the modulated voltage is higher than the defined bandwidth threshold, the control circuit is further configured to close the first switch while keeping the second switch and the third switch open.

19. The wireless device of claim 13, wherein, when the modulation bandwidth of the modulated voltage is lower than or equal to the defined bandwidth threshold, the control circuit is further configured to close the first switch, the second switch, and the third switch.

20. A method for operating a wide-bandwidth power management integrated circuit (PMIC) comprising:
configuring a regular-bandwidth voltage circuit to generate a modulated voltage having a lower modulation bandwidth at a voltage output;
configuring a high-bandwidth voltage circuit to generate the modulated voltage having a higher modulation bandwidth at the voltage output;
activating the regular-bandwidth voltage circuit and deactivating the high-bandwidth voltage circuit when a modulation bandwidth of the modulated voltage is lower than or equal to a defined bandwidth threshold; and
activating the high-bandwidth voltage circuit and deactivating the regular-bandwidth voltage circuit when the modulation bandwidth of the modulated voltage is higher than the defined bandwidth threshold.
